(19) United States
(12) Patent Application Publication
(10) Pub. No.: US 2007/0207322 A1
(43) Pub. Date: Sep. 6, 2007

(54) Semiconductor encapsulating epoxy resin composition and semiconductor device

(75) Inventors: Yasuo Kimura, Annaka-shi (JP); Eiichi Asano, Annaka-shi (JP)

Correspondence Address: BIRCH STEWART KOLASCH & BIRCH, PO BOX 747, FALLS CHURCH, VA, 22040-0747, US

(73) Assignee: Shin-Etsu Chemical Co., Ltd.

(21) Appl. No.: 11/711,661

(22) Filed: Feb. 28, 2007

(30) Foreign Application Priority Data
Mar. 1, 2006 (JP) 2006-054294

(51) Int. Cl. B32B 27/38; H01L 21/56; C08L 63/00; B32B 27/18

(52) U.S. Cl. 428/413; 438/127; 525/524; 523/400

(57) ABSTRACT

An epoxy resin composition comprising (A) a mixture of a naphthalene type epoxy resin and an anthracene type epoxy resin, (B) a curing agent in the form of a naphthalene type phenolic resin, and (C) an inorganic filler is best suited for semiconductor encapsulation.

### CROSS-REFERENCE TO RELATED APPLICATION

This non-provisional application claims priority under 35 U.S.C. §119(a) on Patent Application No. 2006-054294 filed in Japan on Mar. 1, 2006, the entire contents of which are hereby incorporated by reference.

### TECHNICAL FIELD

This invention relates to an epoxy resin composition for semiconductor encapsulation which has good flow, a low coefficient of linear expansion, a high glass transition temperature, minimal moisture absorption, and crack resistance upon lead-free soldering. It also relates to a semiconductor device encapsulated with a cured product of the composition.

### BACKGROUND ART

The current mainstream of semiconductor devices including diodes, transistors, ICs, LSIs and VLSIs are of the resin encapsulation type. Epoxy resins have superior moldability, adhesion, electrical properties, mechanical properties, and moisture resistance to other thermosetting resins. It is thus a common practice to encapsulate semiconductor devices with epoxy resin compositions. In harmony with the recent market trend of electronic equipment toward smaller size, lighter weight and higher performance, efforts are devoted to the fabrication of semiconductor members of larger integration and the promotion of semiconductor mount technology. Under the circumstances, more stringent requirements including lead elimination from solder are imposed on epoxy resins as the semiconductor encapsulant.

Recently, ball grid array (BGA) and QFN packages characterized by a high density mount become the mainstream of IC and LSI packages. For these packages which are encapsulated only on one surface, the problem of warpage after molding becomes more serious. One approach taken in the prior art for improving warpage is to increase the crosslink density of resins to elevate their glass transition temperature. While lead-free solders require higher soldering temperature, such resins have a higher modulus at higher temperature and high moisture absorption. Thus there are left outstanding problems of delamination at the interface between the cured epoxy resin and the substrate and at the interface between the semiconductor chip and the resin paste after solder reflow. On the other hand, for resins with a lower crosslink density, more inorganic filler loadings are effective for providing low water absorption, a low coefficient of expansion and a low modulus at high temperature and expected to be effective for imparting reflow resistance as well. Regrettably, a concomitant increase of viscosity can compromise the flow during molding.

Japanese Patent No. 3,137,202 discloses an epoxy resin composition comprising an epoxy resin and a curing agent wherein the epoxy resin used is 1,1-bis(2,7-diglycidyloxy-1-naphthyl)alkane. This epoxy resin composition in the cured state has good heat resistance and excellent moisture resistance, and overcomes the drawback that cured products of ordinary high-temperature epoxy resin compositions are hard and brittle.

JP-A 2005-15689 describes an epoxy resin composition comprising (A) an epoxy resin comprising (a1) 1,1-bis(2,7-diglycidyloxy-1-naphthyl)alkane, (a2) 1-(2,7-diglycidyloxy-1-naphthyl)-1-(2-glycidyloxy-1-naphthyl)alkane, and (a3) 1,1-bis(2-glycidyloxy-1-naphthyl)alkane, and (B) a curing agent wherein 40 to 95 parts by weight of (a3) is included per 100 parts by weight of (a1), (a2) and (a3) combined. It is described that inclusion of 40 to 95 parts by weight of the resin of formula (1), shown later, wherein m=n=0 is preferred from the standpoints of flow and curability.

These epoxy resin compositions for semiconductor encapsulation, however, are still insufficient in achieving good flow, a low coefficient of linear expansion, a high glass transition temperature, minimal moisture absorption, and soldering crack resistance.

### DISCLOSURE OF THE INVENTION

An object of the invention is to provide an epoxy resin composition for semiconductor encapsulation which has good flow, a low coefficient of linear expansion, a high glass transition temperature, minimal moisture absorption, and crack resistance upon lead-free soldering; and a semiconductor device encapsulated with a cured product of the composition.

Regarding an epoxy resin composition for semiconductor encapsulation comprising an epoxy resin, a curing agent, and an inorganic filler as main components, the inventors have found that by combining two specific epoxy resins of the general formulae (1) and (2), shown below, with a specific phenolic resin, especially of the general formula (3), shown below, there is obtained an epoxy resin composition which is fully flowable and cures into parts having a low coefficient of linear expansion, a high glass transition temperature (Tg), minimal moisture absorption, and crack resistance upon soldering.

Accordingly, the present invention provides an epoxy resin composition for semiconductor encapsulation comprising (A) an epoxy resin, (B) a phenolic resin curing agent having at least one substituted or unsubstituted naphthalene ring in a molecule, and (C) an inorganic filler, the epoxy resin (A) essentially comprising an epoxy resin having the general formula (1) and an epoxy resin having the general formula (2).

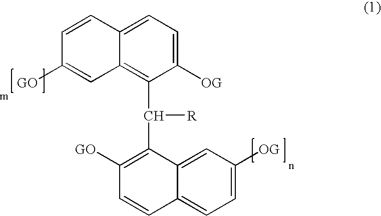

Herein m and n are 0 or 1, R is hydrogen, C₁-C₄ alkyl or phenyl, and G is a glycidyl-containing organic group, with the proviso that 35 to 85 parts by weight of the resin wherein m=0 and n=0 and 1 to 35 parts by weight of the resin wherein m=1 and n=1 are included per 100 parts by weight of the resin of formula (1).

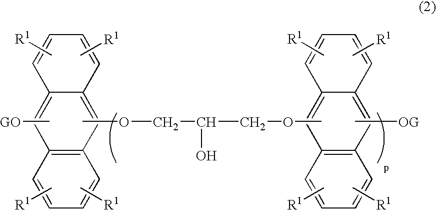

### Herein R¹ is hydrogen, C₁-C₄ alkyl or phenyl, G is a glycidyl-containing organic group, and p is an integer of 0 to 100.

In a preferred embodiment, the epoxy resin of formula (1) and the epoxy resin of formula (2) are present in a weight ratio between 20/80 and 80/20.

In a preferred embodiment, the phenolic resin (B) is a phenolic resin having the general formula (3):

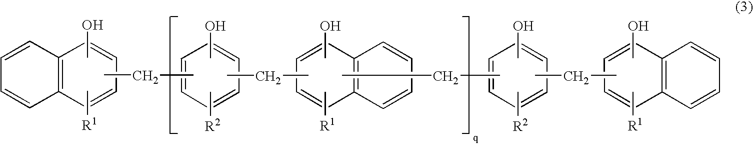

wherein R¹ and R² are each independently hydrogen, C₁-C₄ alkyl or phenyl, and q is an integer of 0 to 10. In a preferred embodiment, 25 to 100 parts by weight of the phenolic resin having formula (3) is included per 100 parts by weight of entire phenolic resins.

The invention also provides a semiconductor device encapsulated with the epoxy resin composition defined above. Typically the semiconductor device comprises a resin or metal substrate, and a semiconductor member mounted on one surface of the resin or metal substrate, wherein the semiconductor member is encapsulated with the epoxy resin composition substantially solely on the one surface of the resin or metal substrate.

### BENEFITS OF THE INVENTION

The epoxy resin composition of the invention is fully flowable and cures into parts having a low coefficient of linear expansion, a high Tg, minimal moisture absorption, and crack resistance upon lead-free soldering. It is best suited for semiconductor encapsulation. The semiconductor device encapsulated with a cured product of the epoxy resin composition is of great worth in the industry.

### BRIEF DESCRIPTION OF THE DRAWING

FIG. 1 is a diagrammatic representation of the IR reflow schedule for reflow resistance measurement.

### DESCRIPTION OF THE PREFERRED EMBODIMENTS

### A. Epoxy Resin

The epoxy resin (A) is a mixture of a first epoxy resin having the general formula (1) and a second epoxy resin having the general formula (2). In a preferred embodiment, 20 to 80 parts by weight of the first epoxy resin of formula (1) and 20 to 80 parts by weight of the second epoxy resin of formula (2) are included per 100 parts by weight of the epoxy resin (A). In a more preferred embodiment, 30 to 70 parts by weight of the first epoxy resin and 30 to 70 parts by weight of the second epoxy resin are included per 100 parts by weight of the epoxy resin (A). If the first epoxy resin is less than 20 parts by weight, reactivity may lower, adversely affecting warpage characteristics. More than 80 parts by weight of the first epoxy resin may adversely affect flow. If the mixing ratio of the first and second epoxy resins is outside the range between 20/80 and 80/20, the epoxy resin composition may not be endowed with the desired properties.

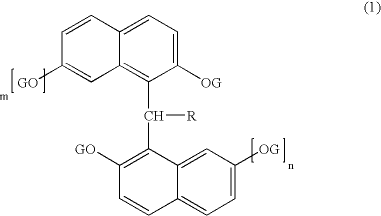

Herein m and n are 0 or 1, R is hydrogen, C₁-C₄ alkyl or phenyl, and G is a glycidyl-containing organic group, with the proviso that 35 to 85 parts by weight of the resin wherein m=0 and n=0 and 1 to 35 parts by weight of the resin wherein m=1 and n=1 are included per 100 parts by weight of the resin of formula (1).

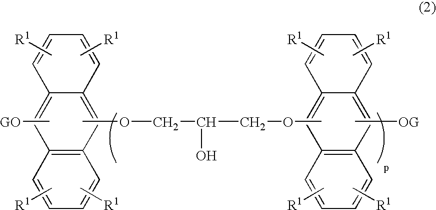

### Herein R¹ is hydrogen, C₁-C₄ alkyl or phenyl, G is a glycidyl-containing organic group, and p is an integer of 0 to 100, preferably 0 to 10, and more preferably 0 to 2.

Examples of R and R¹ include hydrogen atoms, alkyl groups such as methyl, ethyl and propyl, and phenyl groups. One typical example of the glycidyl-containing organic group of G is shown below.

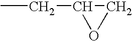

For the naphthalene type epoxy resin having formula (1), it is essential that 35 to 85 parts by weight of the resin wherein m=0 and n=0 and 1 to 35 parts by weight of the resin wherein m=1 and n=1 be present per 100 parts by weight of the resin of formula (1). If the resin wherein m=0 and n=0 is less than 35 parts by weight per 100 parts by weight of the resin of formula (1), the resin composition may have a high viscosity and be less flowable. If the same resin is more than 85 parts by weight, the resin composition may undesirably have an extremely low crosslinking density, less curability and a low Tg. If the resin wherein m=1 and n=1 is more than 35 parts by weight per 100 parts by weight of the resin of formula (1), the resin composition may have an increased crosslinking density and an increased Tg, but be undesirably increased in modulus of elasticity at high temperature. In order that the epoxy resin composition have satisfactory curability, heat resistance and modulus of elasticity at high temperature, it is preferred that the content of the resin wherein m=0 and n=0 be 45 to 70 parts by weight and the content of the resin wherein m=1 and n=1 be 5 to 30 parts by weight.

Specific examples of the epoxy resin of formula (1) are shown below.

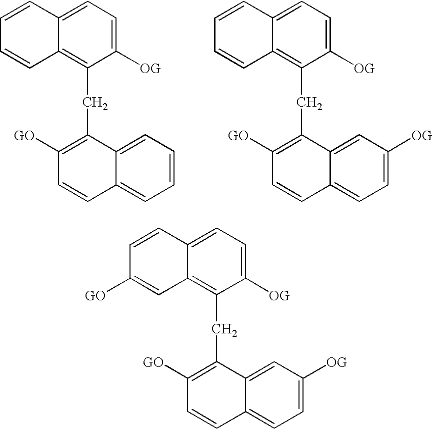

### Note that G is as defined above.

Specific examples of the epoxy resin of formula (2) are shown below.

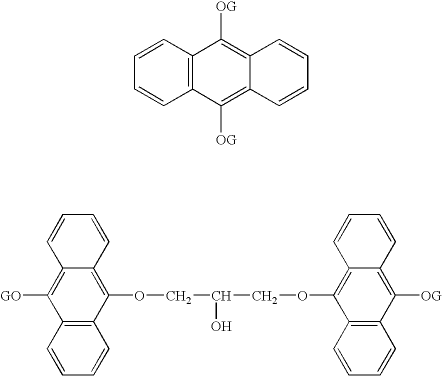

### Note that G is as defined above.

In the inventive composition, another epoxy resin may be used in combination with the epoxy resin (A) as an epoxy resin component. The other epoxy resin used herein is not particularly limited and is selected from prior art well-known epoxy resins including novolac type epoxy resins (e.g., phenol novolac epoxy resins, cresol novolac epoxy resins), triphenolalkane type epoxy resins (e.g., triphenolmethane epoxy resins, triphenolpropane epoxy resins), biphenyl type epoxy resins, phenol aralkyl type epoxy resins, biphenyl aralkyl type epoxy resins, heterocyclic epoxy resins, naphthalene ring-containing epoxy resins other than formula (1), bisphenol type epoxy resins (e.g., bisphenol A epoxy resins, bisphenol F epoxy resins), stilbene type epoxy resins, and halogenated epoxy resins. The other epoxy resins may be employed alone or in combination of two or more.

It is desired that the epoxy resin (A) (i.e., a mixture of first and second epoxy resins) account for 70 to 100% by weight, more preferably 80 to 100% by weight of the entire epoxy resins (i.e., epoxy resin (A)+other epoxy resins). If the proportion of the epoxy resin (A) is less than 70% by weight, the epoxy resin composition of the invention is not endowed with the desired properties.

### B. Curing Agent

A phenolic resin is included in the epoxy resin composition of the invention as a curing agent for the epoxy resin (A). It is a phenolic resin having at least one substituted or unsubstituted naphthalene ring in a molecule. Preferred are phenolic resins having the general formula (3):

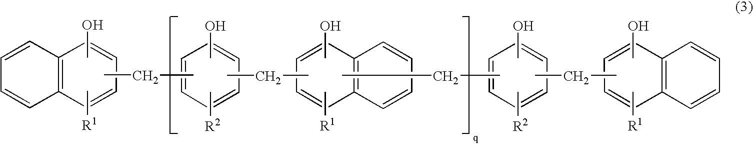

wherein R¹ and R² are each independently hydrogen, C₁-C₄ alkyl or phenyl, and q is an integer of 0 to 10, preferably 0 to 5.

Illustrative examples of R¹ and R² include hydrogen atoms, alkyl groups such as methyl, ethyl and propyl, and phenyl groups.

The use of a curing agent in the form of a naphthalene ring-bearing phenolic resin ensures that the epoxy resin composition in the cured state has a low coefficient of linear expansion, a high Tg, a low modulus of elasticity in a temperature range equal to or above Tg, and minimal water absorption. When the epoxy resin composition is used as an encapsulant for semiconductor devices, the resulting package is improved in crack resistance upon thermal shocks and in warpage.

As the phenolic resin in the epoxy resin composition of the invention, another phenolic resin may be used in combination with the naphthalene phenolic resin of formula (3). The other phenolic resin is not particularly limited, and use may be made of prior art well-known phenolic resins including novolac type phenolic resins (e.g., phenol novolac resins, cresol novolac resins), phenol aralkyl type phenolic resins, biphenyl aralkyl type phenolic resins, biphenyl type phenolic resins, triphenolalkane type phenolic resins (e.g., triphenolmethane phenolic resins, triphenolpropane phenolic resins), alicyclic phenolic resins, heterocyclic phenolic resins, and bisphenol type phenolic resins (e.g., bisphenol A and bisphenol F phenolic resins). These phenolic resins may be employed alone or in combination of two or more.

It is desired that the naphthalene phenolic resin account for 25 to 100% by weight, more preferably 40 to 80% by weight of the entire phenolic resins (i.e., naphthalene phenolic resin+other phenolic resins). If the proportion of the naphthalene phenolic resin is less than 25% by weight, some of the desired properties including heat resistance, moisture absorption and warpage may be lost.

No particular limit is imposed on the proportion of the curing agent (phenolic resin) relative to the epoxy resin. The phenolic resin is preferably used in such amounts that the molar ratio of phenolic hydroxyl groups in the curing agent to epoxy groups in the epoxy resin is from 0.5 to 1.5, and more preferably from 0.8 to 1.2.

### C. Inorganic Filler

THE inorganic filler (C) included in the epoxy resin compositions of the invention may be any suitable inorganic filler commonly used in epoxy resin compositions. Illustrative examples include silicas such as fused silica and crystalline silica, alumina, silicon nitride, aluminum nitride, boron nitride, titanium oxide, glass fibers, and antimony trioxide. No particular limit is imposed on the average particle size and shape of these inorganic fillers as well as the amount thereof. To enhance the crack resistance upon lead-free soldering and flame retardance, the inorganic filler is preferably contained in a larger amount in the epoxy resin composition insofar as this does not compromise moldability.

With respect to the mean particle size and shape of the inorganic filler, spherical fused silica having a mean particle size of 3 to 30 μn, especially 5 to 25 μm is more preferred. It is noted that the mean particle size can be determined as the weight average value or median diameter in particle size distribution measurement by the laser light diffraction technique, for example.

The inorganic filler used herein is preferably surface treated beforehand with a coupling agent such as a silane coupling agent or a titanate coupling agent in order to increase the bond strength between the resin and the inorganic filler. The preferred coupling agents are silane coupling agents including epoxy-functional silanes such as γ-glycidoxypropyltrimethoxysilane, γ-glycidoxypropylmethyldiethoxysilane, and β-(3,4-epoxycyclohexyl)ethyltrimethoxysilane; amino-functional silanes such as N-(β-aminoethyl)-γ-aminopropyltrimethoxysilane, γ-aminopropyltriethoxysilane, and N-phenyl-γ-aminopropyltrimethoxysilane; and mercapto-functional silanes such as γ-mercaptopropyltrimethoxysilane. No particular limitation is imposed on the amount of coupling agent used for surface treatment or the method of surface treatment.

The amount of the inorganic filler (C) loaded is preferably 200 to 1,200 parts, more preferably 500 to 800 parts by weight per 100 parts by weight of the epoxy resin (A) and curing agent (B) combined. A composition with less than 200 pbw of the inorganic filler may have an increased coefficient of expansion, allowing the packages to undergo more warpage so that more stresses may be applied to the semiconductor devices, detracting from the device performance. Additionally, the resin content relative to the entire composition becomes higher, detracting from moisture resistance and crack resistance. A composition with more than 1,200 pbw of the inorganic filler may have too high a viscosity to mold. The content of inorganic filler is preferably 75 to 91% by weight, more preferably 78 to 89% by weight, even more preferably 83 to 88% by weight based on the entire composition.

### Other Components

In addition to the foregoing components, the encapsulating resin compositions of the invention may further include various additives, if necessary. Exemplary additives include cure accelerators such as imidazole compounds, tertiary amine compounds, and phosphorus compounds; stress reducing agents such as thermoplastic resins, thermoplastic elastomers, organic synthetic rubbers, and silicones; waxes such as carnauba wax; colorants such as carbon black; and halogen-trapping agents.

For promoting the cure reaction of the epoxy resin with the curing agent (phenolic resin), a cure accelerator is often used. The cure accelerator is not particularly limited as long as it can promote cure reaction. Useful cure accelerators include phosphorus compounds such as triphenylphosphine, tributylphosphine, tri(p-methylphenyl)phosphine, tri(nonylphenyl)phosphine, triphenylphosphine triphenylborane, tetraphenylphosphine tetraphenylborate and triphenylphosphine benzoquinone adduct; tertiary amine compounds such as triethylamine, benzyldimethylamine, α-methylbenzyldimethylamine, and 1,8-diazabicyclo[5.4.0]undecene-7; and imidazole compounds such as 2-methylimidazole, 2-phenylimidazole, and 2-phenyl-4-methylimidazole.

The cure accelerator may be used in an effective amount for promoting the cure reaction of the epoxy resin and curing agent. When the cure accelerator is a phosphorus compound, tertiary amine compound or imidazole compound as exemplified above, it is preferably used in amounts of 0.1 to 3 parts by weight, more preferably 0.5 to 2 parts by weight per 100 parts by weight of the epoxy resin and curing agent combined.

The parting agent which can be used herein is not particularly limited and may be selected from well-known ones. Suitable parting agents include carnauba wax, rice wax, polyethylene, polyethylene oxide, montanic acid, and montan waxes in the form of esters of montanic acid with saturated alcohols, 2-(2-hydroxyethylamino)ethanol, ethylene glycol, glycerin or the like; stearic acid, stearic esters, stearamides, ethylene bisstearamide, ethylene-vinyl acetate copolymers, and the like, alone or in admixture of two or more. The parting agent is desirably included in an amount of 0.1 to 5 parts, more desirably 0.3 to 4 parts by weight per 100 parts by weight of components (A) and (B) combined.

### Preparation

The inventive epoxy resin compositions may generally be prepared as a molding material by compounding the epoxy resin, curing agent, inorganic filler and optional additives in predetermined proportions, intimately mixing them together in a mixer or the like, then melt mixing the resulting mixture in a hot roll mill, kneader, extruder or the like. The mixture is then cooled and solidified, and subsequently ground to a suitable size so as to give a molding material.

When the components are mixed in a mixer or the like to form a uniform composition, it is preferred for improved shelf stability of the resulting composition to add a silane coupling agent as a wetter.

Examples of suitable silane coupling agents include γ-glycidoxypropyltrimethoxysilane, γ-glycidoxypropylmethyldiethoxysilane, γ-glycidoxypropyltriethoxysilane, p-styryltrimethoxysilane, γ-methacryloxypropylmethyldimethoxysilane, γ-methacryloxypropyltrimethoxysilane, γ-methacryloxypropylmethyldiethoxysilane, γ-methacryloxypropyltriethoxysilane, γ-acryloxypropyltrimethoxysilane, N-(β-aminoethyl)-γ-aminopropylmethyldimethoxysilane, N-(β-aminoethyl)-γ-aminopropyltrimethoxysilane, N-(β-aminoethyl)-γ-aminopropyltriethoxysilane, γ-aminopropyltrimethoxysilane, γ-aminopropyltriethoxysilane, N-phenyl-γ-aminopropyltrimethoxysilane, γ-mercaptopropylmethyldimethoxysilane, γ-mercaptopropyltrimethoxysilane, bis(triethoxypropyl)tetrasulfide, and γ-isocyanatopropyltriethoxysilane. No particular limits are imposed on the amount of silane coupling agent.

The resulting epoxy resin compositions of the invention can be effectively used for encapsulating various types of semiconductor devices. The encapsulation method most commonly used is low-pressure transfer molding. The epoxy resin composition of the invention is preferably molded and cured at a temperature of about 150 to 185° C. for a period of about 30 to 180 seconds, followed by post-curing at about 150 to 185° C. for about 2 to 20 hours.

### EXAMPLE

Examples, and Comparative Examples are given below for further illustrating the invention, but are not intended to limit the invention. In Examples, all parts are by weight.

### Examples 1-9 & Comparative Examples 1-6

Epoxy resin compositions for semiconductor encapsulation were prepared by uniformly melt mixing the components shown in Table 1 in a hot twin-roll mill, followed by cooling and grinding. The components used are identified below.

### Epoxy Resin (A)

Epoxy Resins (a) and (b)

Epoxy resins of formula (1) include epoxy resins A, B and C of the following structures having different values of m and n. Epoxy resins (a) and (b) are mixtures of epoxy resins A, B and C blended in the proportion shown in Table 1.

TABLE 1

| | Blending proportion (wt %) | | |
|---|---|---|---|
| | Epoxy resin A | Epoxy resin B | Epoxy resin C |
| Epoxy resin (a) | 60 | 30 | 10 |
| Epoxy resin (b) | 50 | 35 | 15 |

Epoxy Resin A (m=0, n=0)

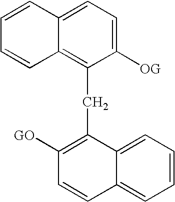

Epoxy Resin B (m=1, n=0, or m=0, n=1)

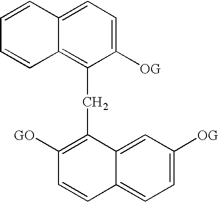

Epoxy Resin C (m=1, n=1)

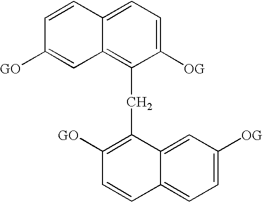

### Epoxy Resin (c)

Epoxy resin (c) has the formula:

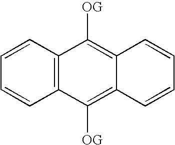

wherein G is

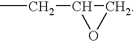

### Epoxy Resin (d)

biphenyl epoxy resin YX400HK, Japan Epoxy Resin Co., Ltd.

### Epoxy Resin (e)

biphenyl aralkyl epoxy resin NC3000, Nippon Kayaku Co., Ltd.

### Epoxy Resin (f) triphenol alkane epoxy resin EPPN-501, Nippon Kayaku Co., Ltd.

### Curing Agent (B)

Phenolic resin (g) has the following formula.

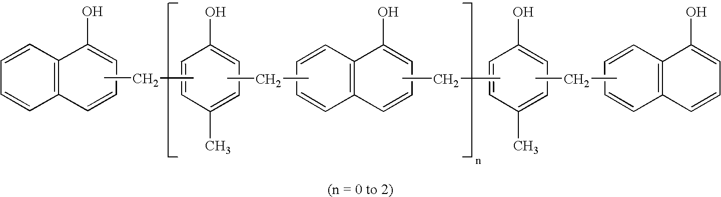

Phenolic resin (h) has the following formula.

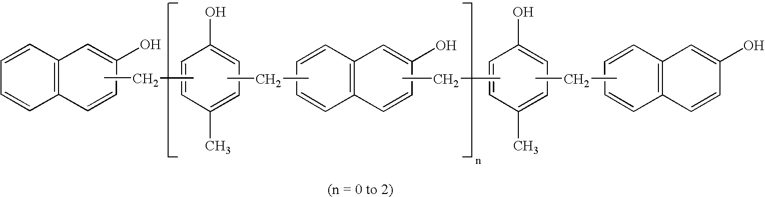

Phenolic resin (i) is a novolac type phenolic resin TD-2131 (Dainippon Ink & Chemicals, Inc.)

### Inorganic Filler

spherical fused silica having an average particle size of 12 μm and a maximum particle size of 75 μm, by Tatsumori K.K.

### Other Additives

Cure accelerator: triphenylphosphine
   (Hokko Chemical Co., Ltd.)
Parting agent: Carnauba Wax
   (Nikko Fine Products Co., Ltd.)
Silane coupling agent: γ-glycidoxypropyltrimethoxysilane KBM-403
   (Shin-Etsu Chemical Co., Ltd.)

Epoxy resin compositions of Examples and Comparative Examples have the formulation shown in Tables 2 and 3 where values are parts by weight (pbw). Properties (1) to (6) of the compositions were measured by the following methods. The results are also shown in Tables 2 and 3.

### (1) Spiral Flow

Measured by molding at 175° C. and 6.9 N/mm² for a molding time of 120 seconds using a mold in accordance with EMMI standards.

### (2) Melt Viscosity

Viscosity was measured at a temperature of 175° C. and a pressure of 10 kgf by an extrusion plastometer through a nozzle having a diameter of 1 mm.

### (3) Glass Transition Temperature (Tg) and Coefficient of Linear Expansion (CE)

Measured by molding at 175° C. and 6.9 N/mm² for a molding time of 120 seconds using a mold in accordance with EMMI standards.

### (4) Moisture Absorption

The composition was molded at 175° C. and 6.9 N/mm² for 2 minutes into a disc of 50 mm diameter and 3 mm thick and post-cured at 180° C. for 4 hours. The disc was held in a temperature/moisture controlled chamber at 85° C. and 85% RH for 168 hours, following which a percent moisture absorption was determined.

(5) Warpage

A silicon chip of 10'10×0.3 mm was mounted on a bismaleimide triazine (BT) resin substrate of 0.40 mm thick. The composition was transfer molded at 175° C. and 6.9 N/mm² for 2 minutes and post-cured at 175° C. for 5 hours, completing a package of 32×32×1.2 mm. Using a laser three-dimensional tester, the height of the package was measured in a diagonal direction to determine changes, the maximum change being a warpage.

### (6) Reflow Resistance

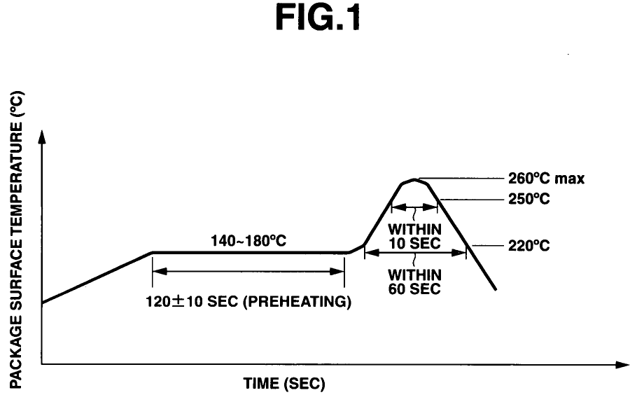

The package used in the warpage measurement was held in a temperature/moisture controlled chamber at 85° C. and 60% RH for 168 hours for moisture absorption. Using an IR reflow apparatus, the package was subjected to three cycles of IR reflow under the conditions shown in FIG. 1. Using a ultrasonic flaw detector, the package was inspected for internal cracks and delamination.

TABLE 2

| | | Example | | | | | | | | |
|---|---|---|---|---|---|---|---|---|---|---|
| Formulation (pbw) | | 1 | 2 | 3 | 4 | 5 | 6 | 7 | 8 | 9 |
| Epoxy | (a) | 4.1 | 2.9 | 1.7 | 4 | 4.2 | | | | 2.4 |
| resin | (b) | | | | | | 4 | 3.9 | 4.1 | |
| | (c) | 1.8 | 2.9 | 4 | 1.7 | 1.8 | 1.7 | 1.7 | 1.8 | 2.4 |
| | (d) | | | | | | | | | |
| | (e) | | | | | | | | | 1.2 |
| | (f) | | | | | | | | | |
| Phenolic | (g) | 4.1 | 4.2 | 4.3 | | 2.8 | 4.3 | | 2.9 | 4.0 |
| resin | (h) | | | | 4.3 | | | 4.4 | | |
| | (i) | | | | | 1.2 | | | 1.2 | |

| Inorganic filler | | 80 | 80 | 80 | 80 | 80 | 80 | 80 | 80 | 80 |
|---|---|---|---|---|---|---|---|---|---|---|
| Cure accelerator | | 0.1 | 0.1 | 0.1 | 0.1 | 0.1 | 0.1 | 0.1 | 0.1 | 0.1 |
| Parting agent | | 0.1 | 0.1 | 0.1 | 0.1 | 0.1 | 0.1 | 0.1 | 0.1 | 0.1 |
| Coupling agent | | 0.1 | 0.1 | 0.1 | 0.1 | 0.1 | 0.1 | 0.1 | 0.1 | 0.1 |
| Spiral flow, cm | | 120 | 130 | 140 | 125 | 123 | 113 | 115 | 120 | 130 |
| Melt viscosity, Pa · s | | 9 | 8 | 7 | 8 | 9 | 10 | 9 | 9 | 8 |
| Tg, ° C. | | 153 | 151 | 150 | 150 | 150 | 156 | 153 | 150 | 146 |
| CE, ppm | | 8 | 8 | 8 | 8 | 8 | 8 | 8 | 8 | 8 |
| Moisture absorption, % | | 0.1 | 0.1 | 0.1 | 0.1 | 0.11 | 0.1 | 0.1 | 0.11 | 0.1 |
| Warpage, μm | | 8 | 10 | 13 | 12 | 20 | 7 | 9 | 12 | 23 |
| Reflow | crack, | 0/20 | 0/20 | 0/20 | 0/20 | 0/20 | 0/20 | 0/20 | 0/20 | 0/20 |
| resistance | defective samples/ | | | | | | | | | |
| | test samples | | | | | | | | | |
| | delamination, | 0/20 | 0/20 | 0/20 | 0/20 | 0/20 | 0/20 | 0/20 | 0/20 | 0/20 |
| | defective samples/ | | | | | | | | | |
| | test samples | | | | | | | | | |

TABLE 3

| | | Comparative Example | | | | | |
|---|---|---|---|---|---|---|---|
| Formulation (pbw) | | 1 | 2 | 3 | 4 | 5 | 6 |
| Epoxy | (a) | 5.3 | 0.6 | 3.2 | | | |
| resin | (b) | | | | | | |
| | (c) | 0.6 | 5.3 | 3.2 | | | |
| | (d) | | | | 6.3 | | |
| | (e) | | | | | 7 | |
| | (f) | | | | | | 6 |
| Phenolic | (g) | 4.1 | 4.3 | | | | |
| resin | (h) | | | | | | |
| | (i) | | | 3.6 | 3.7 | 3 | 4 |
| Inorganic filler | | 80 | 80 | 80 | 80 | 80 | 80 |
| Cure accelerator | | 0.1 | 0.1 | 0.1 | 0.1 | 0.1 | 0.1 |
| Parting agent | | 0.1 | 0.1 | 0.1 | 0.1 | 0.1 | 0.1 |
| Coupling agent | | 0.1 | 0.1 | 0.1 | 0.1 | 0.1 | 0.1 |
| Spiral flow, cm | | 80 | 150 | 132 | 160 | 91 | 98 |
| Melt viscosity, Pa · s | | 12 | 5 | 8 | 5 | 12 | 11 |
| Tg, ° C. | | 157 | 146 | 152 | 110 | 130 | 170 |
| CE, ppm | | 8 | 8 | 8 | 12 | 12 | 12 |
| Moisture absorption, % | | 0.12 | 0.12 | 0.12 | 0.2 | 0.16 | 0.23 |
| Warpage, μm | | 5 | 100 | 38 | 500 | 300 | 50 |
| Reflow | crack, | 0/20 | 0/20 | 0/20 | 10/20 | 0/20 | 20/20 |
| resistance | defective samples/ | | | | | | |
| | test samples | | | | | | |
| | delamination, | 0/20 | 0/20 | 0/20 | 15/20 | 0/20 | 20/20 |
| | defective samples/ | | | | | | |
| | test samples | | | | | | |

Japanese Patent Application No. 2006-054294 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. An epoxy resin composition for semiconductor encapsulation comprising
(A) an epoxy resin,
(B) a phenolic resin curing agent having at least one substituted or unsubstituted naphthalene ring in a molecule, and
(C) an inorganic filler,
said epoxy resin (A) essentially comprising an epoxy resin having the general formula (1) and an epoxy resin having the general formula (2): 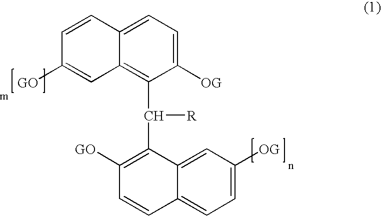
wherein m and n are 0 or 1, R is hydrogen, C₁-C₄ alkyl or phenyl, and G is a glycidyl-containing organic group, with the proviso that 35 to 85 parts by weight of the resin wherein m=0 and n=0 and 1 to 35 parts by weight of the resin wherein m=1 and n=1 are included per 100 parts by weight of the resin of formula (1), 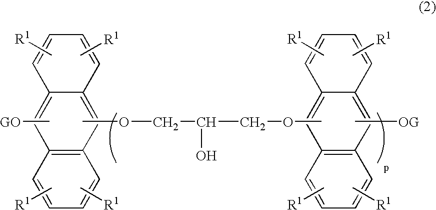
wherein R¹ is hydrogen, C₁-C₄ alkyl or phenyl, G is a glycidyl-containing organic group, and p is an integer of 0 to 100.

2. The epoxy resin composition of claim 1, wherein the phenolic resin (B) is a phenolic resin having the general formula (3): 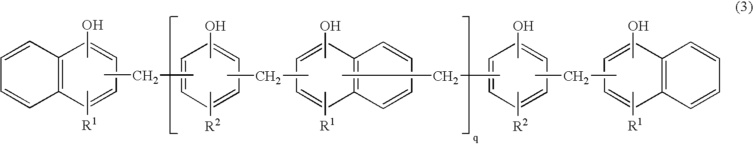
wherein R¹ and R² are each independently hydrogen, C₁-C₄ alkyl or phenyl, and q is an integer of 0 to 10.

3. The epoxy resin composition of claim 2, wherein 25 to 100 parts by weight of the phenolic resin having formula (3) is included per 100 parts by weight of entire phenolic resins.

4. The epoxy resin composition of claim 1, wherein the epoxy resin of formula (1) and the epoxy resin of formula (2) are present in a weight ratio between 20/80 and 80/20.

5. A semiconductor device encapsulated with the epoxy resin composition of claim 1.

6. The semiconductor device of claim 5, comprising a resin or metal substrate, and a semiconductor member mounted on one surface of the resin or metal substrate, wherein the semiconductor member is encapsulated with the epoxy resin composition substantially solely on the one surface of the resin or metal substrate.
